(19) United States
(12) Patent Application Publication
(10) Pub. No.: US 2025/0393398 A1
(43) Pub. Date: Dec. 25, 2025

(54) ELECTRONIC DEVICE AND ELECTRONIC APPARATUS

(71) Applicant: PanelSemi Corporation, New Taipei City (TW)

(72) Inventor: Wun-Zong CHANG, New Taipei City (TW)

(21) Appl. No.: 19/244,198

(22) Filed: Jun. 20, 2025

Related U.S. Application Data
(60) Provisional application No. 63/662,634, filed on Jun. 21, 2024.

(51) Int. Cl. H10K 59/121; H10H 29/14; H10H 29/32

(52) U.S. Cl. CPC H10K 59/1213; H10H 29/142; H10H 29/32

(57) ABSTRACT

An electronic device and an electronic apparatus are disclosed. The electronic device includes a substrate and a plurality of element units. The substrate defines a plurality of edges and a functional region. The plurality of element units are arranged in the functional region, each of the element units includes one or more functional elements and a driving circuit. The one or more functional elements defines an element geometric center, and the driving circuit defines a circuit geometric center. In one of the one or more element units adjacent to one edge of the substrate, the circuit geometric center is located at a side of the element geometric center and away from the corresponding edge of the substrate.

### CROSS REFERENCE TO RELATED APPLICATIONS

This Non-provisional application claims priority to U.S. provisional patent application with Ser. No. 63/662,634 filed on Jun. 21, 2024. This and all other extrinsic materials discussed herein are incorporated by reference in their entirety.

### BACKGROUND

### Technology Field

The disclosure relates to an electronic device provide with borderless function.

### Description of Related Art

Seamless display has been a major trend in modern electronic devices and has been used in different electronic devices, such as smart phones, tablets, televisions, or large display devices. Seamless display has better visual experience and can be arranged side by side to form a larger display device. However, the arrangement of the traces near the edges of the seamless display affect how “seamless” the seamless display can be.

### SUMMARY

One or more exemplary embodiments of this disclosure are to provide an electronic device and an electronic apparatus describing the relative positional configuration of the functional elements and the driver circuit in the device, especially the innovative configuration near the edge thereof. Such a configuration helps achieve a more seamless experience and uniformity of components on the devices after tiling.

An electronic device comprises a substrate and a plurality of element units. The substrate defines a plurality of edges and a functional region. The plurality of element units are arranged in the functional region, each of the element units comprises one or more functional elements and a driving circuit. The one or more functional elements defines an element geometric center, and the driving circuit defines a circuit geometric center. In one of the one or more element units adjacent to one edge of the substrate, the circuit geometric center is located at a side of the element geometric center and away from the corresponding edge of the substrate.

In one embodiment, the driving circuit comprises a plurality of transistors construed by a semiconductor material pattern, the semiconductor material pattern constitutes the circuit geometric center.

In one embodiment, each of the element units is a pixel unit, and each of the functional element is an inorganic light-emitting diode (LED) or an organic light-emitting diode (OLED).

In one embodiment, between the two element units that are farthest apart in a direction of the functional region, a gap between adjacent two of the circuit geometric centers is greater than a gap between adjacent two of the element geometric centers.

In one embodiment, the circuit geometric centers are set between the two element geometric centers.

In one embodiment, in the direction of the functional region, a gap between the circuit geometric center and the corresponding edge is greater than half of a gap between adjacent two of the element geometric centers.

An electronic apparatus comprises a plurality of above-mentioned electronic devices tiled with one another by jointing the edge of the substrate, wherein between the two adjacent element units at individual functional region of two adjacent electronic devices, a gap between two circuit geometric centers is greater than a gap between two element geometric centers.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1 is a top view showing the arrangement of driving circuits and element units;

FIG. 2 is a partial-enlargement view of FIG. 1;

FIG. 3 is a partial-enlargement view of FIG. 2;

FIG. 4 is a circuit diagram of one embodiment of the present invention;

FIG. 5A is a schematic diagram showing layout of one pixel of present invention;

FIG. 5B a schematic diagram showing relative relations of functional elements and semiconductor material pattern in one pixel of present invention; and

FIG. 6 is a schematic diagram showing multiple electronic devices of the present invention joining together.

### DETAILED DESCRIPTION OF THE DISCLOSURE

The disclosure will become more fully understood from the detailed description and accompanying drawings, which are given for illustration only, and thus are not limitative of the present disclosure.

The present disclosure will be apparent from the following detailed description, which proceeds with reference to the accompanying drawings, wherein the same references relate to the same elements.

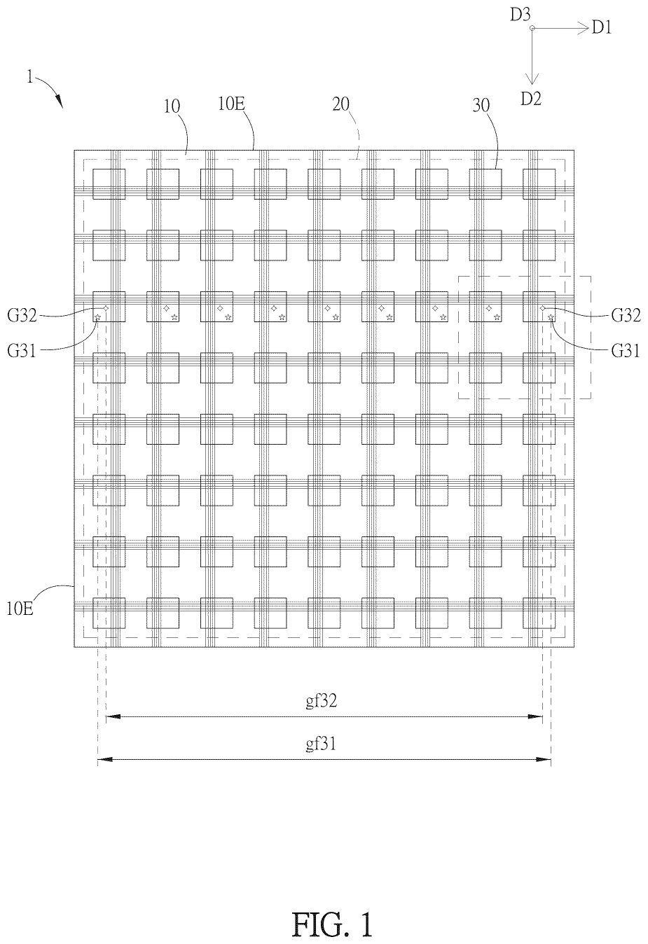

An electronic device 1, as illustrated in FIG. 1, includes a substrate 10 and a plurality of element units 30. The substrate 10 defines a plurality of edges 10E and a functional region 20. The element units 30 are arranged in the functional region 20.

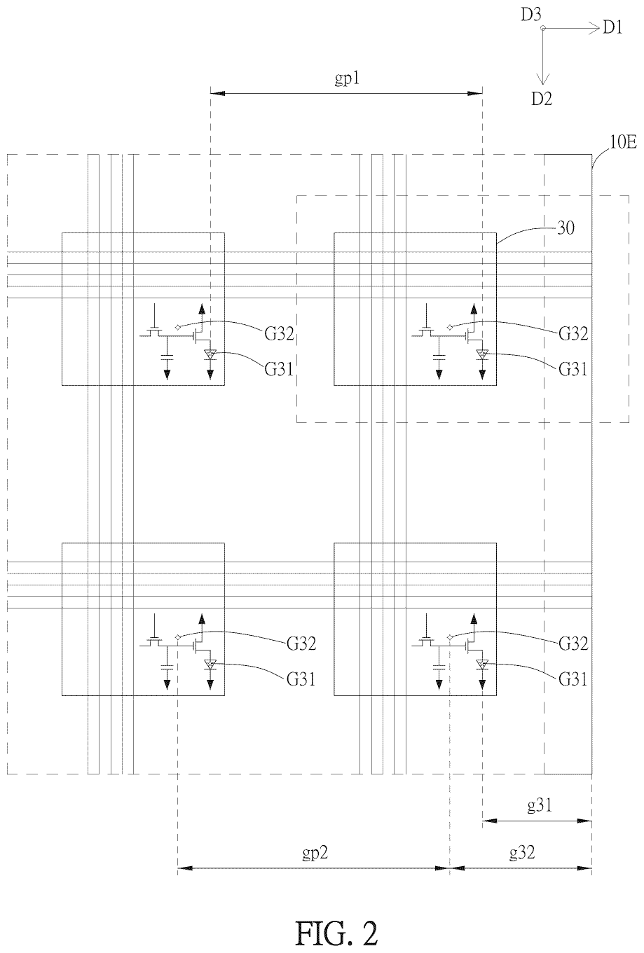

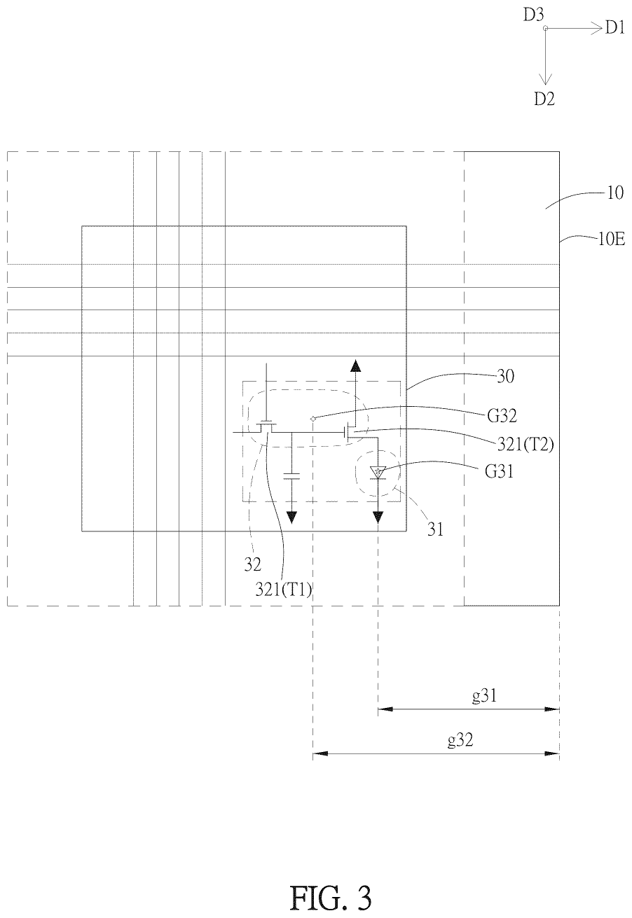

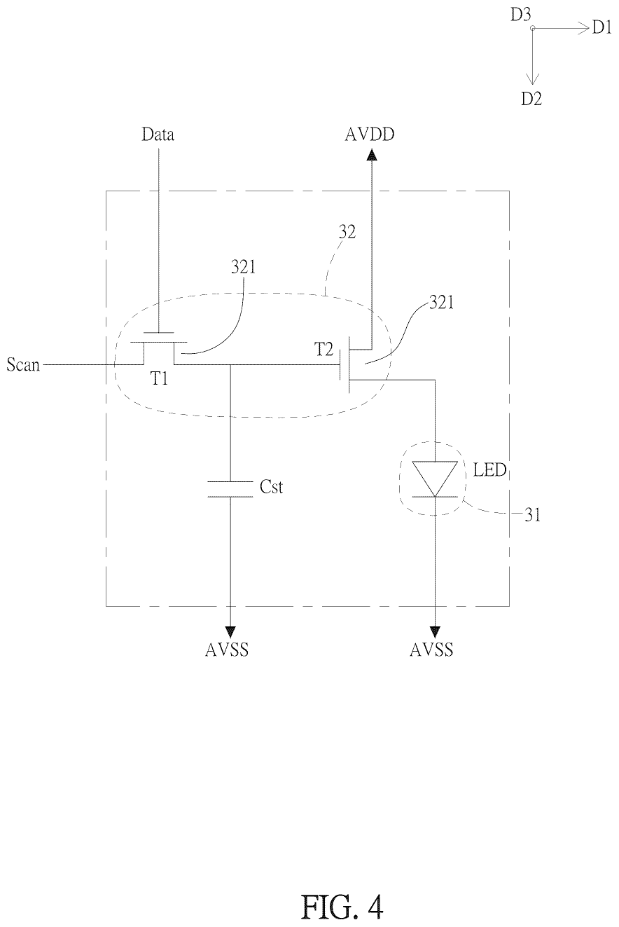

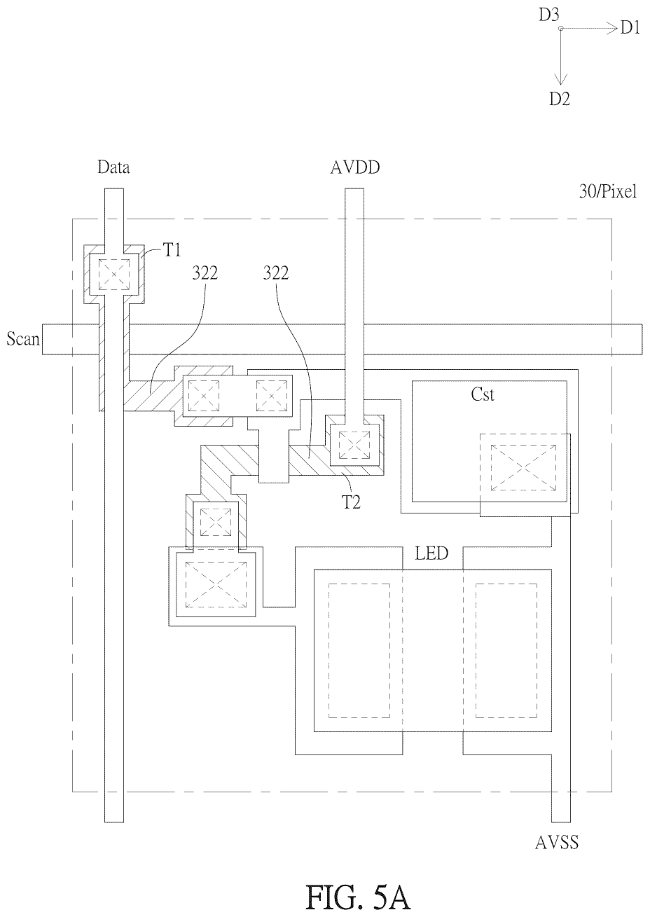

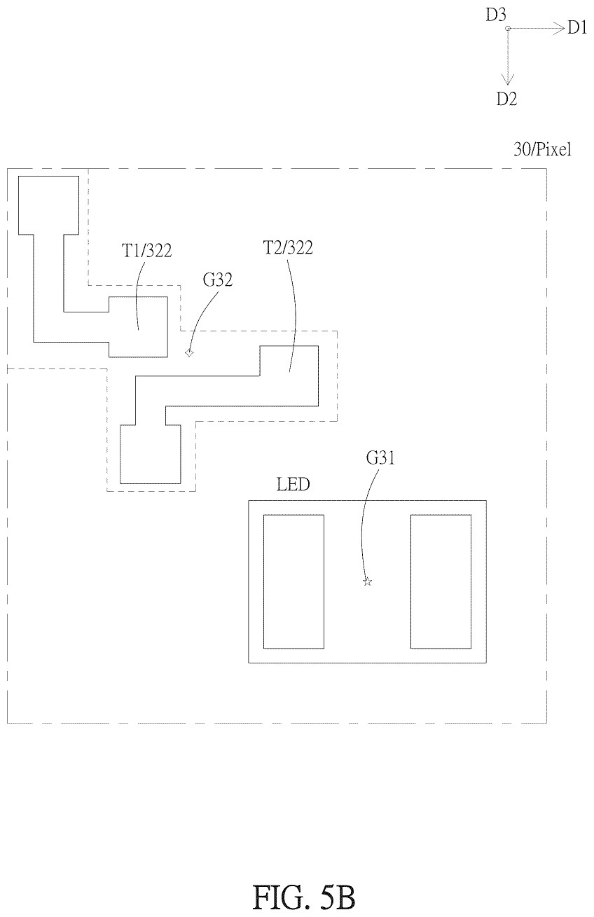

As illustrated in FIG. 2 and FIG. 3, each of the element units 21 includes one or more functional elements 31 and a driving circuit 32. The functional element 31 defines an element geometric center G31 in FIG. 3, while plural of the functional elements 31, not shown in the present disclosure, are supposed to define an element geometric center together. The driving circuit 32 defines a circuit geometric center G32 and includes a plurality of transistors 321, as illustrated as a circuit diagram in FIG. 4. The transistors 321 are construed by a semiconductor material pattern 322 in which the semiconductor material pattern 322 constitutes the circuit geometric center G32. Take a display device as an example, the layout of the element units 30, functional elements 31 and driving circuit 32 are shown in FIG. 5A and FIG. 5B. In FIGS. 5A and 5B, one pixel of the display device is considered as the element unit 30 and the LEDs are considered as the functional elements 31 of the present invention. The driving circuit 32 comprises the transistors T1, T2, which is construed by a semiconductor material pattern 322. The pixel also comprises capacity Cst (ex. storage capacity) and traces such as data line, scan line, AVDD, AVSS, and etc.

As illustrated in FIG. 3, in one of the element units 30 adjacent to one edge 10E of the substrate 10, the circuit geometric center G32 is located at a side of the element geometric center G31 and away from the corresponding edge 10E of the substrate 10.

In one case, each of the element units 30 is a pixel unit, and the functional element 31 is an inorganic light-emitting diode (LED) or an organic light-emitting diode (OLED), and the electronic device is as of a display device.

In one embodiment, in a row or a column of the element units 30 in a direction D1 in this embodiment, or a direction D2 in another embodiment, of the functional region 20, a gap g31 between the element geometric center G31 and the corresponding edge 10E, and a gap g32 between the circuit geometric center G32 and the corresponding edge 10E are defined. The gap g32 is greater than half of a gap gp1 between adjacent two of the element geometric centers G31 in the direction D1, as illustrated in FIG. 2 and FIG. 3. To be noted, the gap gp1 of any adjacent two of the element geometric centers G31 may be fixed, but not limited.

In one embodiment, in a row or a column of the element units 30 in a direction D1 or D2 of the functional region 20, between the two element units 30 that are farthest apart in the direction D1 of the functional region 20 as in FIG. 1, a gap gp2 between adjacent two of the circuit geometric centers G32 is greater than the gap gp1 between adjacent two of the element geometric centers G31; in another embodiment, the two circuit geometric centers G32 are set between the two element geometric centers G31.

A gap gf32 between two circuit geometric centers G32 of two element units 30 that are farthest apart is less than a gap gf31 between two element geometric centers G31 of two element units 30 that are farthest apart. In this embodiment, in the direction D1 of the functional region 20, the gap g32, taking reference with FIG. 3, is greater than half of the gap gp1 between adjacent two of the element geometric centers G31.

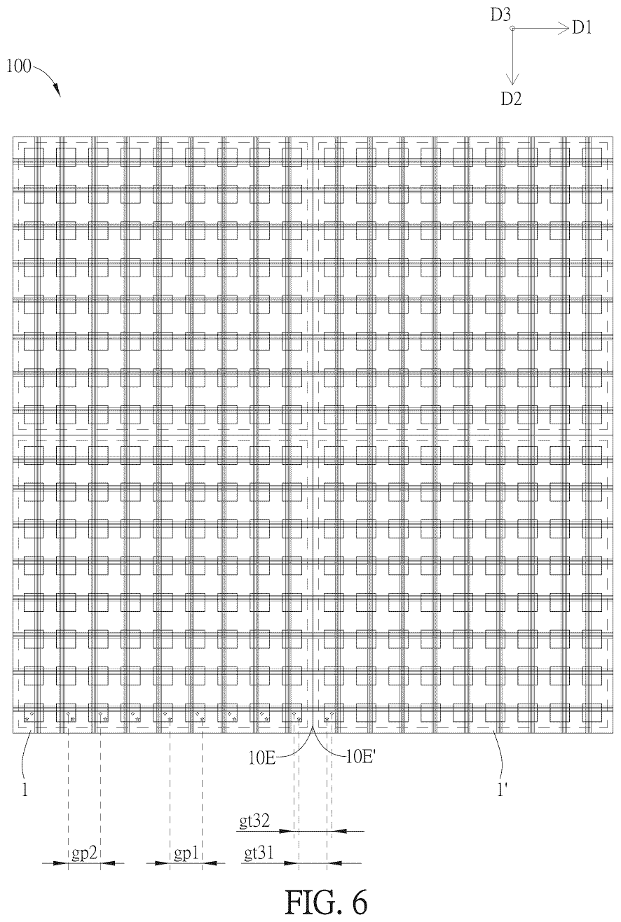

In FIG. 6, an electronic apparatus 100 provided which is tiled by a plurality of electronic devices 1. The electronic devices 1 are tiled with one another by jointing the edge 10E of the substrate 10. Take the electronic device 1, 1′ as example, this two electronic devices 1, 1′ are joined by the edge 10E, 10E′. Between two nearest adjacent element units 30 of this two adjacent electronic devices 1, 1′, a gap gt32 between the two nearest circuit geometric center G32 of the two adjacent electronic devices 1, 1′ is greater than a gap gt31 between the two nearest element geometric centers G31 of the two adjacent electronic devices 1, 1′. In one embodiment, the electronic apparatus 100 are tiled by a plurality of display devices (electronic devices 1), and the functional elements 31 of the electronic device 1 are lighting members, the gap gt31 can be equal to a pixel pitch of the display device (electronic devices 10). In another embodiment, the gap gt31 may be not greater than the gap gp1 of the electronic device 1. Additionally, the gap gt31 and the gap gp1 are less than the gap gt32.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. An electronic device, comprising:
a substrate defining a plurality of edges and a functional region; and
a plurality of element units, arranged in the functional region, each of the element units comprising one or more functional elements and a driving circuit, the one or more functional elements defining an element geometric center, and the driving circuit defining a circuit geometric center; wherein
in one of the one or more element units adjacent to one edge of the substrate, the circuit geometric center is located at a side of the element geometric center and away from the corresponding edge of the substrate.

2. The electronic device as claimed in claim 1, wherein the driving circuit comprises a plurality of transistors construed by a semiconductor material pattern, the semiconductor material pattern constitutes the circuit geometric center.

3. The electronic device as claimed in claim 1, wherein each of the element units is a pixel unit, and each of the functional element is an inorganic light-emitting diode (LED) or an organic light-emitting diode (OLED).

4. The electronic device as claimed in claim 1, wherein between the two element units that are farthest apart in a direction of the functional region, a gap between adjacent two of the circuit geometric centers is greater than a gap between adjacent two of the element geometric centers.

5. The electronic device as claimed in claim 4, wherein the circuit geometric centers are set between the two element geometric centers.

6. The electronic device as claimed in claim 4, wherein in the direction of the functional region, a gap between the circuit geometric center and the corresponding edge is greater than half of a gap between adjacent two of the element geometric centers.

7. The electronic device as claimed in claim 1, wherein in a direction of the functional region, a gap between the circuit geometric center and the corresponding edge is greater than half of a gap between adjacent two of the element geometric centers.

8. An electronic apparatus, comprising a plurality of electronic devices according to claim 1 tiled with one another by jointing the edge of the substrate, wherein between the two adjacent element units at individual functional region of two adjacent electronic devices, a gap between two circuit geometric centers is greater than a gap between two element geometric centers.

9. The electronic apparatus as claimed in claim 8, wherein the driving circuit comprises a plurality of transistors construed by a semiconductor material pattern, the semiconductor material pattern constitutes the circuit geometric center.

10. The electronic apparatus as claimed in claim 8, wherein each of the element units is a pixel unit, and each of the functional element is an inorganic light-emitting diode (LED) or an organic light-emitting diode (OLED).

11. The electronic apparatus as claimed in claim 8, wherein between the two element units that are farthest apart in a direction of the functional region, a gap between adjacent two of the circuit geometric centers is greater than a gap between adjacent two of the element geometric centers.

12. The electronic apparatus as claimed in claim 11, wherein the circuit geometric centers are set between the two element geometric centers.

13. The electronic apparatus as claimed in claim 11, wherein in the direction of the functional region, a gap between the circuit geometric center and the corresponding edge is greater than half of a gap between adjacent two of the element geometric centers.

14. The electronic apparatus as claimed in claim 8, wherein in a direction of the functional region, a gap between the circuit geometric center and the corresponding edge is greater than half of a gap between adjacent two of the element geometric centers.
